(19) United States
(12) Patent Application Publication
(10) Pub. No.: US 2024/0217864 A1
(43) Pub. Date: Jul. 4, 2024

(54) GLASS BLOCK AND METHOD FOR PRODUCING SAME, AND MEMBER FOR SEMICONDUCTOR PRODUCTION APPARATUS

(71) Applicant: AGC Inc., Tokyo (JP)

(72) Inventors: Kazuki KANEHARA, Chiyoda-ku (JP); Seiji INABA, Chiyoda-ku (JP); Shuhei OGAWA, Chiyoda-ku (JP)

(73) Assignee: AGC Inc., Tokyo (JP)

(21) Appl. No.: 18/600,865

(22) Filed: Mar. 11, 2024

Related U.S. Application Data
(63) Continuation of application No. PCT/JP2022/033485, filed on Sep. 6, 2022.

(30) Foreign Application Priority Data
Sep. 14, 2021 (JP) 2021-149104
Oct. 12, 2021 (JP) 2021-167594
Nov. 26, 2021 (JP) 2021-192308

(51) Int. Cl. C03C 3/097; C03B 5/235; C03B 19/02; C03B 25/02; C03C 3/06; C03C 3/078; C03C 3/087; C03C 3/089; C03C 3/091; C03C 3/095; C03C 3/11; C03C 3/12; H01L 21/683; H01L 21/687

(52) U.S. Cl. CPC C03C 3/097; C03B 5/235; C03B 19/02; C03B 25/02; C03C 3/06; C03C 3/078; C03C 3/087; C03C 3/089; C03C 3/091; C03C 3/095; C03C 3/111; C03C 3/125; C03C 2201/02; H01L 21/6833; H01L 21/68757

(57) ABSTRACT

The present invention relates to a glass block including: Si; and at least one of Mg and Ca, and satisfying, in terms of mol %, 49.0% or less of B₂O₃, 11.5% or less of P₂O₅, 10.0 to 59.5% of a (=SiO₂+B₂O₃+P₂O₅+GeO₂), 66.5% or less of (a+Al₂O₃), 7.0% or less of Ga₂O₃, 0.44 or less of b (=Al₂O₃+Ga₂O₃+In₂O₃)/a, 20.0% or more of R²O (R²: alkaline earth metal), 50.0% or less of MgO, MgO≥BaO, CaO≥BaO, SrO≥BaO, MgO≥SrO, CaO≥SrO, 1.2% or less of R¹₂O (R¹: alkali metal), 4.8% or less of TiO₂ or ZrO₂, 9.5% or less of MnO₂, 11.8% or less of ZnO, 0.067 or less of Ta₂O₅/SiO₂, 15.0% or less of an impurity element, and 0.20 or less of F/O.

### CROSS-REFERENCE TO RELATED APPLICATIONS

This is a continuation of International Application No. PCT/JP2022/033485 filed on Sep. 6, 2022, and claims priority from Japanese Patent Applications No. 2021-149104 filed on Sep. 14, 2021, No. 2021-167594 filed on Oct. 12, 2021, and No. 2021-192308 filed on Nov. 26, 2021, the entire contents of which are incorporated herein by reference.

### TECHNICAL FIELD

The present invention relates to a glass block, a method for manufacturing the same, and a member for a semiconductor manufacturing apparatus.

### BACKGROUND ART

A member used in a semiconductor manufacturing apparatus is often exposed to plasma and gradually worn during operation of the semiconductor manufacturing apparatus. The member which has been worn is replaced with a new member.

In recent years, as a product manufactured by the semiconductor manufacturing apparatus has become 3D-integrated and more complex, a plasma environment to which the member is exposed become more severe, and in this case, it is frequently necessary to replace the member.

However, during the replacement of the member, the semiconductor manufacturing apparatus cannot be operated. Therefore, when replacement frequency of the member increases, production efficiency of the product decreases.

Therefore, the member used in the semiconductor manufacturing apparatus is required to have a longer lifespan. That is, good plasma resistance is required.

Examples of the semiconductor manufacturing apparatus include a plasma etching apparatus.

In the plasma etching apparatus, members such as a top plate (conductor type), a microwave introduction tube, a lift pin, various nozzles, an edge ring, an electrostatic chuck, a shower plate, and a protective cover for a sensor inside a chamber are mounted.

In the related art, materials such as a cordierite-based sintered body is used as the members (see Patent Literature 1).

### CITATION LIST

### Patent Literature

Patent Literature 1: JPH09-295863A

### SUMMARY OF INVENTION

### Technical Problem

For example, a material used as a window material (member for observing an inside of an apparatus from an outside) of the semiconductor manufacturing apparatus is required to have good plasma resistance and good transparency.

The present invention has been made in view of the above points, and an object thereof is to provide a material excellent in plasma resistance and transparency.

### Solution to Problem

As a result of intensive studies, the inventors of the present invention have found that the above object can be achieved by adopting the following configuration, and have completed the present invention.

That is, the present invention has the following configuration.
[1] A glass block including:
silicon; and
at least one of magnesium and calcium, in which
when an alkali metal element is expressed as R¹ and an alkaline earth metal element is expressed as R², in terms of mol percentage based on oxides,
a content of B₂O₃ is 49.0 mol % or less,
a content of P₂O₅ is 11.5 mol % or less,
a total of contents of SiO₂, B₂O₃, P₂O₅, and GeO₂ is 10.0 mol % or more and 59.5 mol % or less,
a total of contents of SiO₂, B₂O₃, P₂O₅, GeO₂, and Al₂O₃ is 66.5 mol % or less,
a content of Ga₂O₃ is 7.0 mol % or less,
a ratio b/a of a total b of contents of Al₂O₃, Ga₂O₃, and In₂O₃ to a total a of the contents of SiO₂, B₂O₃, P₂O₅, and GeO₂ is 0.44 or less,
a content of R²O is 20.0 mol % or more,
a content of MgO is 50.0 mol % or less,
the content of MgO is equal to or more than a content of BaO, a content of CaO is equal to or more than the content of BaO, and a content of SrO is equal to or more than the content of BaO,
the content of MgO is equal to or more than the content of SrO, and the content of CaO is equal to or more than the content of SrO,
a content of R¹₂O is 1.2 mol % or less,
a content of TiO₂ or ZrO₂ is 4.8 mol % or less,
a content of MnO₂ is 9.5 mol % or less,
a content of ZnO is 11.8 mol % or less,
a ratio Ta₂O₅/SiO₂ of a content of Ta₂O₅ to a content of SiO₂ is 0.067 or less,
a content of an impurity element in terms of an oxide is 15.0 mol % or less, provided that the impurity element is a metal element excluding silicon, boron, phosphorus, germanium, aluminum, gallium, indium, an alkaline earth metal element, yttrium, an alkali metal element, titanium, zirconium, manganese, zinc, and tantalum, and a ratio F/O of a content F of fluorine to a content O of oxygen is 0.20 or less.
[2] A method for manufacturing the glass block according to the [1], the method including:
melting a glass raw material by heating; and
molding the obtained molten glass, followed by annealing.
[3] A member for a semiconductor manufacturing apparatus including:
the glass block according to the [1].

### Advantageous Effects of Invention

According to the present invention, a material excellent in plasma resistance and transparency can be provided.

### DESCRIPTION OF EMBODIMENTS

The terms used in the present invention have the following meanings.

A numerical range represented using “to” means a range including numerical values described before and after “to” as a lower limit value and an upper limit value.

Moreover, in the present description, “mass” is synonymous with “weight”.

### [Glass Block]

A glass block according to the present invention includes:
silicon; and
at least one of magnesium and calcium, and
when an alkali metal element is expressed as R¹ and an alkaline earth metal element is expressed as R², in terms of mol percentage based on oxides,
a content of B₂O₃ is 49.0 mol % or less,
a content of P₂O₅ is 11.5 mol % or less,
a total of contents of SiO₂, B₂O₃, P₂O₅, and GeO₂ is 10.0 mol % or more and 59.5 mol % or less,
a total of contents of SiO₂, B₂O₃, P₂O₅, GeO₂, and Al₂O₃ is 66.5 mol % or less,
a content of Ga₂O₃ is 7.0 mol % or less,
a ratio b/a of a total b of contents of Al₂O₃, Ga₂O₃, and In₂O₃ to a total a of the contents of SiO₂, B₂O₃, P₂O₅, and GeO₂ is 0.44 or less,
a content of R²O is 20.0 mol % or more,
a content of MgO is 50.0 mol % or less,
the content of MgO is equal to or more than a content of BaO, a content of CaO is equal to or more than the content of BaO, and a content of SrO is equal to or more than the content of BaO,
the content of MgO is equal to or more than the content of SrO, and the content of CaO is equal to or more than the content of SrO,
a content of R¹₂O is 1.2 mol % or less,
a content of TiO₂ or ZrO₂ is 4.8 mol % or less,
a content of MnO₂ is 9.5 mol % or less,
a content of ZnO is 11.8 mol % or less,
a ratio Ta₂O₅/SiO₂ of a content of Ta₂O₅ to the content of SiO₂ is 0.067 or less,
a content of an impurity element in terms of an oxide is 15.0 mol % or less, provided that the impurity element is a metal element excluding silicon, boron, phosphorus, germanium, aluminum, gallium, indium, an alkaline earth metal element, yttrium, an alkali metal element, titanium, zirconium, manganese, zinc, and tantalum, and
a ratio F/O of a content F of fluorine to a content O of oxygen is 0.20 or less.

Hereinafter, the glass block is simply referred to as “glass”, and the glass block according to the present invention is also referred to as the “present glass block” or the “present glass”.

The present glass block is excellent in plasma resistance. This is presumed to be because by using the above configuration, a rate of deterioration due to plasma irradiation is reduced.

Further, the present glass block is excellent in transparency. This is presumed to be because by using the above configuration, crystallization is prevented, thereby preventing generation of a heterogeneous phase.

Here, examples of the heterogeneous phase include, in addition to a crystalline phase, a colloidal metal and ceramic particles.

That is, the present glass block preferably does not include these heterogeneous phases (crystalline phase, colloidal metal, ceramic particles, and the like) for the reason that the glass block has excellent transparency.

In a semiconductor manufacturing apparatus, a transparent member in the related art which is used in an environment exposed to plasma is, for example, a quartz member.

However, quartz has insufficient plasma resistance.

On the other hand, the present glass block has excellent plasma resistance and excellent transparency.

Hereinafter, the present glass block will be described in detail.

First, a composition (glass composition) of the present glass block will be described below. That is, contents of elements contained in the present glass block (expressed in terms of mol percentage based on oxides) will be described.

### <Si, B, P, and Ge>

The present glass block includes silicon (Si).

The present glass block may further include boron (B), phosphorus (P), and germanium (Ge).

### <<SiO₂>>

The content of SiO₂ in the present glass block is preferably in a range of 17.0 mol % or more and 59.5 mol % or less.

For the reason that the present glass block has more excellent transparency, the content of SiO₂ is preferably 17.0 mol % or more, more preferably 22.0 mol % or more, still more preferably 27.0 mol % or more, yet still more preferably 32.0 mol % or more, particularly preferably 35.0 mol % or more, more particularly preferably 37.0 mol % or more, even still more preferably 39.0 mol % or more, and most preferably 41.0 mol % or more.

For the reason that the present glass block has more excellent plasma resistance and transparency, the content of SiO₂ is preferably 59.5 mol % or less, more preferably 57.0 mol % or less, still more preferably 55.0 mol % or less, yet still more preferably 53.0 mol % or less, particularly preferably 51.0 mol % or less, more particularly preferably 49.0 mol % or less, very particularly preferably 47.0 mol % or less, and most preferably 45.0 mol % or less.

<<B₂O₃>>

For the reason that the present glass block has excellent plasma resistance, the content of B₂O₃ is 49.0 mol % or less, preferably 40.0 mol % or less, more preferably 30.0 mol % or less, still more preferably 20.0 mol % or less, yet still more preferably 15.0 mol % or less, particularly preferably 10.0 mol % or less, very particularly preferably 5.0 mol % or less, and most preferably 1.0 mol % or less.

A lower limit of the content of B₂O₃ is preferably zero.

<<P₂O₅>>

For the reason that the present glass block has excellent plasma resistance, the content of P₂O₅ is 11.5 mol % or less, preferably 9.0 mol % or less, more preferably 7.0 mol % or less, still more preferably 5.5 mol % or less, yet still more preferably 4.0 mol % or less, particularly preferably 2.0 mol % or less, and most preferably 1.0 mol % or less.

A lower limit of the content of P₂O₅ is preferably zero.

### <<GeO₂>>

For the reason that the present glass block has excellent plasma resistance, a content of GeO₂ is preferably 5.5 mol % or less, more preferably 4.0 mol % or less, still more preferably 2.0 mol % or less, and particularly preferably 1.0 mol % or less.

A lower limit of the content of GeO₂ is preferably zero.

### <Al, Ga, and In>

The present glass block may include aluminum (Al), gallium (Ga), and indium (In).

<<Al₂O₃>>

A content of Al₂O₃ in the present glass block is preferably in a range of 0.0 mol % or more and 27.5 mol % or less.

For the reason that the present glass block has more excellent transparency, the content of Al₂O₃ is preferably 27.5 mol % or less, more preferably 22.0 mol % or less, still more preferably 18.0 mol % or less, yet still more preferably 13.0 mol % or less, particularly preferably 9.0 mol % or less, very particularly preferably 5.0 mol % or less, and most preferably 1.0 mol % or less.

From the viewpoint of preventing precipitation of a foreign substance in the present glass block, the content of Al₂O₃ is preferably 0.0 mol % or more, more preferably 1.0 mol % or more, still more preferably 2.0 mol % or more, yet still more preferably 3.0 mol % or more, particularly preferably 4.0 mol % or more, and most preferably 5.0 mol % or more.

<<Ga₂O₃>>

For the reason that the present glass block has excellent plasma resistance and transparency, the content of Ga₂O₃ is 7.0 mol % or less, preferably 3.0 mol % or less, more preferably 1.0 mol % or less, and still more preferably 0.5 mol % or less.

A lower limit of the content of Ga₂O₃ is preferably zero.

<<In₂O₃>>>

For the reason that the present glass block has more excellent plasma resistance and transparency, a content of In₂O₃ is preferably 5.0 mol % or less, more preferably 3.0 mol % or less, and still more preferably 1.0 mol % or less.

A lower limit of the content of In₂O₃ is preferably zero.

<A: Total of SiO₂, B₂O₃, P₂O₅, and GeO₂>

The total (a) of the contents of SiO₂, B₂O₃, P₂O₅, and GeO₂ of the present glass block is 10.0 mol % or more and 59.5 mol % or less.

For the reason that the present glass block has excellent transparency, the total (a) of the contents of SiO₂, B₂O₃, P₂O₅, and GeO₂ is 10.0 mol % or more, preferably 17.0 mol % or more, more preferably 22.0 mol % or more, still more preferably 27.0 mol % or more, yet still more preferably 32.0 mol % or more, particularly preferably 35.0 mol % or more, more particularly preferably 37.0 mol % or more, even still more preferably 39.0 mol % or more, and most preferably 41.0 mol % or more.

For the reason that the present glass block has excellent plasma resistance, the total (a) of the contents of SiO₂, B₂O₃, P₂O₅, and GeO₂ is 59.5 mol % or less, preferably 57.0 mol % or less, more preferably 55.0 mol % or less, still more preferably 53.0 mol % or less, yet still more preferably 51.0 mol % or less, particularly preferably 49.0 mol % or less, very particularly preferably 47.0 mol % or less, and most preferably 45.0 mol % or less.

<A+Al₂O₃: Total of SiO₂, B₂O₃, P₂O₅, GeO₂, and Al₂O₃>

For the reason that the present glass block has excellent plasma resistance, the total (a+Al₂O₃) of the contents of SiO₂, B₂O₃, P₂O₅, GeO₂, and Al₂O₃ is 66.5 mol % or less, preferably 63.0 mol % or less, more preferably 60.0 mol % or less, still more preferably 57.0 mol % or less, yet still more preferably 54.0 mol % or less, particularly preferably 51.0 mol % or less, and most preferably 48.0 mol % or less.

On the other hand, for the reason that the present glass block has more excellent transparency, the total (a+Al₂O₃) of the contents of SiO₂, B₂O₃, P₂O₅, GeO₂, and Al₂O₃ is preferably 10.0 mol % or more, more preferably 17.0 mol % or more, and still more preferably 22.0 mol % or more.

That is, the total (a+Al₂O₃) of the contents of SiO₂, B₂O₃, P₂O₅, GeO₂, and Al₂O₃ is preferably in a range of 10.0 mol % or more and 66.5 mol % or less.

<Ratio (b/a)>

For the reason that the present glass block has excellent transparency, the ratio (b/a) of the total b of contents (unit: mol %) of Al₂O₃, Ga₂O₃, and In₂O₃ to the total a of contents (unit: mol %) of SiO₂, B₂O₃, P₂O₅, and GeO₂ is 0.44 or less, preferably 0.36 or less, more preferably 0.29 or less, still more preferably 0.22 or less, yet still more preferably 0.16 or less, particularly preferably 0.12 or less, and most preferably 0.09 or less.

A lower limit of the ratio (b/a) is preferably zero.

### <R²>

The present glass block may include the alkaline earth metal element (R²).

Examples of the alkaline earth metal element (R²) include beryllium (Be), magnesium (Mg), calcium (Ca), strontium (Sr), barium (Ba), and radium (Ra).

However, the present glass block includes at least one of Mg and Ca as an essential element.

### <<R²O>>

For the reason that the present glass block has excellent plasma resistance, the content of R²O is 20.0 mol % or more, preferably 29.0 mol % or more, more preferably 36.0 mol % or more, still more preferably 40.0 mol % or more, particularly preferably 43.0 mol % or more, even still more preferably 46.0 mol % or more, and most preferably 49.0 mol % or more.

An upper limit of the content of R²O is not particularly limited, but is, for example, 80.0 mol % or less, preferably 70.0 mol % or less, more preferably 65.0 mol % or less, still more preferably 60.0 mol % or less, particularly preferably 56.0 mol % or less, and most preferably 52.0 mol % or less.

That is, the content of R²O in the present glass block is preferably in a range of 0.0 mol % or more and 80.0 mol % or less.

### <<MgO>

For the reason that the present glass block has excellent transparency, the content of MgO is 50.0 mol % or less, preferably 40.0 mol % or less, more preferably 35.0 mol % or less, still more preferably 30.0 mol % or less, yet still more preferably 25.0 mol % or less, particularly preferably 20.0 mol % or less, even still more preferably 15.0 mol % or less, and most preferably 10.0 mol % or less.

On the other hand, for the reason that the present glass block has more excellent plasma resistance, the content of MgO is preferably 1.0 mol % or more, more preferably 3.0 mol % or more, and still more preferably 5.0 mol % or more.

That is, the content of MgO in the present glass block is preferably in a range of 1.0 mol % or more and 50.0 mol % or less.

### <<CaO>>

The content of CaO in the present glass block is preferably in a range of 20.0 mol % or more and 69.0 mol % or less.

For the reason that the present glass block has excellent plasma resistance, the content of CaO is preferably 20.0 mol % or more, more preferably 29.0 mol % or more, still more preferably 36.0 mol % or more, yet still more preferably 40.0 mol % or more, particularly preferably 43.0 mol % or more, even still more preferably 46.0 mol % or more, and most preferably 49.0 mol % or more.

On the other hand, for the reason that the present glass block has more excellent transparency, the content of CaO is preferably 69.0 mol % or less, more preferably 66.0 mol % or less, still more preferably 63.0 mol % or less, yet still more preferably 60.0 mol % or less, particularly preferably 57.0 mol % or less, even still more preferably 54.0 mol % or less, and most preferably 51.0 mol % or less.

### <<Total of MgO and CaO>>

A total of contents of MgO and CaO in the present glass block is preferably in a range of 20.0 mol % or more and 69.0 mol % or less.

For the reason that the present glass block has excellent plasma resistance, the total of the contents of MgO and CaO is preferably 20.0 mol % or more, more preferably 29.0 mol % or more, still more preferably 36.0 mol % or more, yet still more preferably 40.0 mol % or more, particularly preferably 43.0 mol % or more, even still more preferably 46.0 mol % or more, and most preferably 49.0 mol % or more.

On the other hand, for the reason that the present glass block has more excellent transparency, the total of the contents of MgO and CaO is preferably 69.0 mol % or less, more preferably 66.0 mol % or less, still more preferably 63.0 mol % or less, yet still more preferably 60.0 mol % or less, particularly preferably 57.0 mol % or less, even still more preferably 54.0 mol % or less, and most preferably 51.0 mol % or less.

### <<SrO>>

For the reason that the present glass block has excellent transparency, the content of SrO is preferably 60.0 mol % or less, more preferably 30.0 mol % or less, still more preferably 10.0 mol % or less, particularly preferably 5.0 mol % or less, and most preferably 1.0 mol % or less.

A lower limit of the content of SrO is preferably zero.

### <<BaO>>

For the reason that the present glass block has more excellent transparency, the content of BaO is preferably 30.0 mol % or less, more preferably 25.0 mol % or less, still more preferably 20.0 mol % or less, yet still more preferably 15.0 mol % or less, particularly preferably 10.0 mol % or less, even still more preferably 5.0 mol % or less, and most preferably 1.0 mol % or less.

A lower limit of the content of BaO is preferably zero.

### <<MgO≥BaO, CaO≥BaO, and SrO≥BaO>

For the reason that the present glass block has excellent plasma resistance, the content (unit: mol %) of MgO is equal to or greater than the content (unit: mol %) of BaO, and preferably larger than the content (unit: mol %) of BaO.

For the same reason, the content (unit: mol %) of CaO is equal to or greater than the content (unit: mol %) of BaO, and preferably greater than the content (unit: mol %) of BaO.

For the same reason, the content (unit: mol %) of SrO is equal to or greater than the content (unit: mol %) of BaO, and preferably greater than the content (unit: mol %) of BaO.

### <<MgO≥SrO and CaO≥SrO>>

For the reason that the present glass block has excellent plasma resistance, the content (unit: mol %) of MgO is equal to or greater than the content (unit: mol %) of SrO, and preferably larger than the content (unit: mol %) of SrO.

For the same reason, the content (unit: mol %) of CaO is equal to or greater than the content (unit: mol %) of SrO, and preferably greater than the content (unit: mol %) of SrO.

### <Y>

The present glass block may include yttrium (Y).

A content of Y₂O₃ in the present glass block is preferably 5.0 mol % or less, more preferably 3.0 mol % or less, and still more preferably 1.0 mol % or less.

A lower limit of the total content of Y₂O₃ is preferably zero.

### <R¹>

The present glass block may include the alkali metal element (R¹).

Examples of the alkali metal element (R¹) include lithium (Li), sodium (Na), potassium (K), rubidium (Rb), cesium (Cs), and francium (Fr). Among these, substantially, lithium (Li), sodium (Na), and potassium (K) are preferable.

<<R¹₂O>>

For the reason that the present glass block has excellent plasma resistance, the content of R¹₂O is 1.2 mol % or less, preferably 0.8 mol % or less, more preferably 0.4 mol % or less, still more preferably 0.1 mol % or less, particularly preferably 0.05 mol % or less, very particularly preferably 0.01 mol % or less, and most preferably 0.002 mol % or less.

A lower limit of the content of R¹₂O is preferably zero.

### <Ti, Zr, Mn, Zn, and Ta>

The present glass block may include titanium (Ti), zirconium (Zr), manganese (Mn), zinc (Zn), and tantalum (Ta).

<<TiO₂ and ZrO₂>>

For the reason that the present glass block has excellent plasma resistance, the content of TiO₂ or ZrO₂ is 4.8 mol % or less, preferably 3.5 mol % or less, more preferably 2.5 mol % or less, and still more preferably 1.0 mol % or less.

A lower limit of the content of TiO₂ or ZrO₂ is preferably zero.

### <<TiO>

For the reason that the present glass block has excellent plasma resistance, the content of TiO₂ is preferably 4.8 mol % or less, more preferably 3.5 mol % or less, still more preferably 2.5 mol % or less, and particularly preferably 1.0 mol % or less.

The lower limit of the content of TiO₂ is preferably zero.

### <<ZrO₂>>

For the reason that the present glass block has excellent plasma resistance, a content of ZrO₂ is preferably 4.8 mol % or less, more preferably 3.5 mol % or less, still more preferably 2.5 mol % or less, and particularly preferably 1.0 mol % or less.

A lower limit of the content of ZrO₂ is preferably zero.

### <<MnO₂>>

For the reason that the present glass block has excellent plasma resistance, the content of MnO₂ is 9.5 mol % or less, preferably 6.0 mol % or less, more preferably 3.0 mol % or less, and still more preferably 1.0 mol % or less.

A lower limit of the content of MnO₂ is preferably zero.

### <<ZnO>>

For the reason that the present glass block has excellent plasma resistance, the content of ZnO is 11.8 mol % or less, preferably 7.0 mol % or less, more preferably 4.0 mol % or less, and still more preferably 1.0 mol % or less.

A lower limit of the content of ZnO is preferably zero.

<<Ta₂O₅>>

For the reason that the present glass block has excellent plasma resistance, the content of Ta₂O₅ is preferably 6.0 mol % or less, more preferably 3.0 mol % or less, and still more preferably 1.0 mol % or less.

A lower limit of the content of Ta₂O₅ is preferably zero.

<Ratio (Ta₂O₅/SiO₂)>

For the reason that the present glass block has excellent transparency, the ratio (Ta₂O₅/SiO₂) of the content (unit: mol %) of Ta₂O₅ to the content (unit: mol %) of SiO₂ is 0.067 or less, preferably 0.060 or less, more preferably 0.050 or less, still more preferably 0.040 or less, yet still more preferably 0.030 or less, particularly preferably 0.020 or less, and most preferably 0.010 or less.

A lower limit of the ratio (Ta₂O₅/SiO₂) is preferably zero.

### <Impurity Element>

For the reason that the present glass block has excellent plasma resistance, the content of the impurity element in terms of an oxide is 15.0 mol % or less, preferably 12.5 mol % or less, more preferably 10.0 mol % or less, still more preferably 7.5 mol % or less, yet still more preferably 5.0 mol % or less, particularly preferably 1.0 mol % or less, very particularly preferably 0.5 mol % or less, and most preferably 0.05 mol % or less.

A lower limit is preferably zero.

The impurity element is metal element excluding silicon (Si), boron (B), phosphorus (P), germanium (Ge), aluminum (Al), gallium (Ga), indium (In), an alkaline earth metal element (R²), yttrium (Y), an alkali metal element (R¹), titanium (Ti), or zirconium (Zr), manganese (Mn), zinc (Zn), and tantalum (Ta).

Specific examples of the impurity element include Cu, Fe, Ni, Cr, Sn, Co, V, Bi, Se, Ce, Er, and Nd.

A content of Cu in terms of an oxide specifically means a content of CuO.

A content of Fe in terms of an oxide specifically means a content of Fe₂O₃.

A content of Ni in terms of an oxide specifically means a content of NiO.

A content of Cr in terms of an oxide specifically means a content of Cr₂O₃.

A content of Sn in terms of an oxide specifically means a content of SnO₂.

A content of Co in terms of an oxide specifically means a content of Co₃O₄.

A content of V in terms of an oxide specifically means a content of V₂O₅.

A content of Bi in terms of an oxide specifically means a content of Bi₂O₃.

A content of Se in terms of an oxide specifically means a content of SeO₂.

A content of Ce in terms of an oxide specifically means a content of CeO₂.

A content of Er in terms of an oxide specifically means a content of Er₂O₃.

A content of Nd in terms of an oxide specifically means a content of Nd₂O₃.

The content (expressed in mole percentage based on an oxide) of each of the above-mentioned elements (excluding Si) in the glass block is measured using an X-ray fluorescence device (XRF) (ZSX100e manufactured by Rigaku Corporation). That is, X-ray intensity of each element on a surface of the glass block is measured and quantitatively analyzed to thereby obtain the content of each element.

The content of SiO₂ in the glass block is determined as follows.

First, a powder sample is taken from a center of the glass block by grinding, and a total oxygen amount Z1 in the glass block is obtained by an infrared absorption method using an oxygen/hydrogen analyzer (ROH-600 manufactured by LECO Corporation).

An oxygen amount Z3 is calculated by subtracting an amount Z2 of oxygen bound to the elements (excluding Si) contained in the glass block in the stoichiometric composition from the total oxygen amount Z1 in the glass block (oxygen amount Z3=total oxygen amount Z1−oxygen amount Z2).

Assuming that the entire oxygen amount Z3 has been used for bonding with silicon atoms, the oxygen amount Z3 is converted to an amount of SiO₂. The amount of SiO₂ obtained in this manner is set as the content of SiO₂ in the glass block.

### <Ratio (F/O)>

For the reason that the present glass block has excellent plasma resistance, the ratio (F/O) of the content of fluorine (F) to the content of oxygen (O) is 0.20 or less, preferably 0.15 or less, more preferably 0.10 or less, and still more preferably 0.05 or less.

A lower limit of the ratio (F/O) is preferably zero.

The ratio (F/O) in the glass block is determined as follows.

First, an F atom concentration (unit: atom %) and an O atom concentration (unit: atom %) are obtained on any one surface of the glass block by using an X-ray photoelectron spectrometer (JPS-9000MC manufactured by JEOL Ltd.). The obtained ratio of the F atom concentration to the O atom concentration is defined as the ratio (F/O) of the glass block.

### <N Content>

For the reason that the present glass block has more excellent transparency, a content (N content) of nitrogen (N) in the present glass block is preferably small.

Specifically, the N content is preferably 9.0% by mass or less, more preferably 7.0% by mass or less, still more preferably 5.0% by mass or less, yet still more preferably 4.0% by mass or less, particularly preferably 3.0% by mass or less, very particularly preferably 2.0% by mass or less, and most preferably 1.0% by mass or less.

A lower limit of the N content is preferably zero.

The N content is measured by a secondary ion mass soectrometry (SIMS). For the measurement, a mass spectrometer (TOF.SIMS5, manufactured by ION-TOF GmbH) is used.

### <Expansion Coefficient>

From the viewpoint of preventing cracking at the time of manufacturing the present glass block, an average thermal expansion coefficient (hereinafter, also simply referred to as “expansion coefficient”) of the present glass block at 50° C. to 350° C. is preferably 9.0 ppm/° C. or less, more preferably 8.0 ppm/° C. or less, still more preferably 7.0 ppm/° C. or less, yet still more preferably 6.0 ppm/° C. or less, particularly preferably 5.5 ppm/° C. or less, very particularly preferably 5.0 ppm/° C. or less, and most preferably 4.5 ppm/° C. or less.

An expansion coefficient is measured using a differential thermal expansion meter in accordance with a method described in JIS R 3102-1995.

### <Visible Light Transmittance>

The present glass block is excellent in transparency. Specifically, for example, visible light transmittance of the present glass block is 75% or more.

The visible light transmittance of the present glass block is preferably 78% or more, more preferably 81% or more, still more preferably 84% or more, yet still more preferably 87% or more, particularly preferably 90% or more, and most preferably 93% or more. An upper limit is preferably 100%.

The visible light transmittance is measured by the method according to JIS R 3106 (1998).

In order to keep the visible light transmittance within the above range, it is preferable to set the content of each component as described above and to manufacture the glass block by a method (the present manufacturing method) to be described later.

### <Porosity>

A porosity of the present glass block is, for example, 3.0 vol % or less. Accordingly, the present glass block is more excellent in plasma resistance.

For the reason that the present glass block has further excellent plasma resistance, the porosity of the present glass block is preferably 2.5 vol % or less, more preferably 2.0 vol % or less, still more preferably 1.5 vol % or less, yet still more preferably 1.0 vol % or less, particularly preferably 0.5 vol % or less, and most preferably 0.1 vol % or less. A lower limit is preferably zero.

The porosity is obtained according to the open porosity calculation method described in JIS R 1634: 1998 “Method for measuring sintered body density and open porosity of fine ceramics”.

In order to keep the porosity within the above range, it is preferable to set the content of each component as described above and to manufacture the glass block by the method (the present manufacturing method) to be described later.

### <Shape>

Examples of a shape of the present glass block include a plate shape (for example, a disc shape and a flat sheet shape), a spherical shape, a spheroidal shape, and the like, and is appropriately selected according to an application.

The “glass block”, in any form, is at least a concept free of a glass frit, a glass powder and a glass fiber.

When the present glass block has a sheet shape, an area of at least one surface (for example, a main surface) of the present glass block is preferably 25 mm² or more, more preferably 100 mm² or more, still more preferably 500 mm² or more, yet still more preferably 1,000 mm² or more, particularly preferably 5,000 mm² or more, more particularly preferably 10,000 mm² or more, very particularly preferably 40,000 mm² or more, and most preferably 90,000 mm² or more.

When the present glass block has the sheet shape, a thickness of the present glass block (thickness of a thinnest portion) is preferably 0.3 mm or more, more preferably 0.5 mm or more, still more preferably 1 mm or more, yet still more preferably 3 mm or more, particularly preferably 6 mm or more, more particularly preferably 10 mm or more, even still more preferably 15 mm or more, and most preferably 20 mm or more.

On the other hand, for the reason that the crystallization of the present glass block is prevented and the transparency is more excellent, a thickness of the present glass block is preferably 500 mm or less, more preferably 100 mm or less, still more preferably 80 mm or less, yet still more preferably 60 mm or less, even still more preferably 50 mm or less, particularly preferably 40 mm or less, and most preferably 30 mm or less.

That is, the thickness of the present glass block is preferably in a range of 0.3 mm or more and 500 mm or less.

### <Application>

The present glass block can be suitably used, for example, as a window material of a semiconductor manufacturing apparatus. However, the application of the present glass block is not limited thereto. The present glass block can be used, for example, as a member to be mounted on a plasma etching apparatus, and examples of the member include a top plate, a microwave introduction tube, a lift pin, a nozzle, an edge ring, an electrostatic chuck, a shower plate, and a protective cover for a sensor inside a chamber.

### [Method for Manufacturing Glass Block]

Next, a method for manufacturing the present glass block (hereinafter, also referred to as “the present manufacturing method”) will be described. In this manufacturing method, generally, glass raw materials are melted by heating, and the obtained molten glass is molded, followed by annealing.

More specifically, first, various glass raw materials are weighed and mixed such that compositions of the glass block to be obtained are the above-described glass compositions.

Next, the mixed glass raw materials are heated and melted using a glass melting furnace or the like. At this time, refining, homogenization, and the like are appropriately performed on the molten material by a known method. Thus, molten glass is obtained.

Thereafter, the obtained molten glass is molded into a desired shape, followed by annealing. A molding method is not particularly limited, and examples thereof include a float method, a press method, a fusion method, and a down-draw method. After the obtained molten glass is molded into a temporary shape and then annealed, and the obtained temporary shaped body may be subjected to processing such as cutting. Thus, a glass block having a desired shape is obtained.

If necessary, processing such as grinding and polishing may be performed on the obtained glass block.

A temperature (hereinafter, also referred to as “melting temperature”) at which the glass raw materials are heated and melted is preferably 1650° C. or lower, more preferably 1600° C. or lower, and still more preferably 1550° C. or lower, for the reason that manufacturing characteristics are excellent.

Further, from the viewpoint of increasing heat resistance of the glass, the melting temperature is preferably 1200° C. or higher, more preferably 1300° C. or higher, and particularly preferably 1400° C. or higher.

That is, the melting temperature is preferably in a range of 1200° C. or higher and 1650° C. or lower.

A time (hereinafter also referred to as “melting time”) for heating and melting the glass raw materials is preferably 24 hours or less, more preferably 12 hours or less, still more preferably 10 hours or less, yet still more preferably 8 hours or less, particularly preferably 6 hours or less, and most preferably 4 hours or less, from the viewpoint of refining property. Further, from the viewpoint of the homogeneity of the glass, the melting time is preferably 1 hour or more, more preferably 2 hours or more, and particularly preferably 3 hours or more.

That is, the melting time is preferably in a range of 1 hour or more and 24 hours or less.

A cooling rate for cooling the molten glass is preferably 0.5° C./min or more, more preferably 1° C./min or more, still more preferably 5° C./min or more, and particularly preferably 10° C./min or more from the viewpoint of crystal acceleration.

Further, from the viewpoint of preventing the glass from being broken, the cooling rate is preferably 30° C./min or less, more preferably 20° C./min or less, and particularly preferably 15° C./min or less.

That is, the cooling rate is preferably in a range from 0.5° C./min or more to 30° C./min or less.

In the semiconductor manufacturing apparatus, a member in the related art which is used in the environment exposed to plasma is, for example, a sapphire member.

However, since sapphire is manufactured by a single crystal growth method, the manufacturing characteristics are deteriorated, and there is a limit to a size that can be manufactured. Further, since the sapphire is a hard-to-work material and is therefore very expensive.

On the other hand, since the present glass block is obtained by the above-described present manufacturing method, the manufacturing characteristics can be improved and the size can also be changed as appropriate. Furthermore, the present glass block is easier to process than the sapphire and is therefore less expensive.

As described above, the present specification discloses the following configuration.
[1] A glass block including:
silicon; and
at least one of magnesium and calcium, in which
when an alkali metal element is expressed as R¹ and an alkaline earth metal element is expressed as R², in terms of mol percentage based on oxides,
a content of B₂O₃ is 49.0 mol % or less,
a content of P₂O₅ is 11.5 mol % or less,
a total of contents of SiO₂, B₂O₃, P₂O₅, and GeO₂ is 10.0 mol % or more and 59.5 mol % or less,
a total of contents of SiO₂, B₂O₃, P₂O₅, GeO₂, and Al₂O₃ is 66.5 mol % or less,
a content of Ga₂O₃ is 7.0 mol % or less,
a ratio b/a of a total b of contents of Al₂O₃, Ga₂O₃, and In₂O₃ to a total a of the contents of SiO₂, B₂O₃, P₂O₅, and GeO₂ is 0.44 or less,
a content of R²O is 20.0 mol % or more,
a content of MgO is 50.0 mol % or less,
the content of MgO is equal to or more than a content of BaO, a content of CaO is equal to or more than the content of BaO, and a content of SrO is equal to or more than the content of BaO,
the content of MgO is equal to or more than the content of SrO, and the content of CaO is equal to or more than the content of SrO,
a content of R¹₂O is 1.2 mol % or less,
a content of TiO₂ or ZrO₂ is 4.8 mol % or less,
a content of MnO₂ is 9.5 mol % or less,
a content of ZnO is 11.8 mol % or less,
a ratio Ta₂O₅/SiO₂ of a content of Ta₂O₅ to a content of SiO₂ is 0.067 or less,
a content of an impurity element in terms of an oxide is 15.0 mol % or less, provided that the impurity element is a metal element excluding silicon, boron, phosphorus, germanium, aluminum, gallium, indium, an alkaline earth metal element, yttrium, an alkali metal element, titanium, zirconium, manganese, zinc, and tantalum, and
a ratio F/O of a content F of fluorine to a content O of oxygen is 0.20 or less.
<2> The glass block according to the <1>, in which
the content of SiO₂ is 17.0 mol % or more.
<3> The glass block according to the <1> or <2>, in which
the content of SiO₂ is 59.5 mol % or more.
<4> The glass block according to any one of the <1> to <3>, in which
the content of Al₂O₃ is 27.5 mol % or less.
<5> The glass block according to any one of the <1> to <4>, in which
a total of the contents of MgO and CaO is 20.0 mol % or more.
<6> The glass block according to any one of the <1> to <5>, in which
the total of the contents of MgO and CaO is 69.0 mol % or less.
<7> The glass block according to any one of the <1> to <6>, in which
the content of CaO is 20.0 mol % or more and 69.0 mol % or less.
<8> The glass block according to any one of the <1> to <7>, in which
the content of BaO is 30.0 mol % or less.
<9> The glass block according to any one of the <1> to <8>, having an average thermal expansion coefficient at 50° C. to 350° C. of 9.0 ppm/° C. or less.
<10> The glass block according to any one of the <1> to <9>, having a visible light transmittance of 75% or more.
<11> The glass block according to any one of the <1> to <10>, having a porosity of 3.0 vol % or less.
<12> A method for manufacturing the glass block according to any one of the <1> to <11>, the method including:
melting a glass raw material by heating; and
molding the obtained molten glass, followed by annealing.
<13> The method for manufacturing the glass block according to the <12>, in which
a temperature at which the glass raw material is heated and melted is 1,650° C. or lower.
<14> A member for a semiconductor manufacturing apparatus including:
the glass block according to any one of the <1> to <11>.
<15> The member for a semiconductor manufacturing apparatus according to the <14>, in which
the member is to be mounted on a plasma etching apparatus, and is a top plate, a microwave introduction tube, a lift pin, a nozzle, an edge ring, an electrostatic chuck, a shower plate, or a protective cover for a sensor inside a chamber.

### EXAMPLES

Hereinafter, the present invention will be specifically described with reference to Examples. However, the present invention is not limited to Examples to be described below.

Hereinafter, Examples 1 to 33 are Working Examples, and Examples 34 to 53 are Comparative Examples.

### Examples 1 to 53

A glass block in each of Examples was obtained as follows.

Glass raw materials were weighed and mixed such that the glass blocks to be obtained contained compositions (expressed in terms of mol percentage based on oxides) shown in the following Tables 1 to 6 and were 400 g.

The mixed glass raw material was placed in a platinum crucible, placed in an electric furnace, and heated at a temperature of 1500° C. to 1700ºC for about 3 hours to melt, followed by refining and homogenization to thereby obtain molten glass.

A part of the obtained molten glass was poured into a metal mold, held at a temperature approximately 50° C. higher than a glass transition point for 1 hour, and cooled to room temperature at a rate of 0.5° C./min to thereby obtain a sheet-shaped glass block (area of main surface: 10,000 mm² and thickness: 10 mm).

However, Examples 47 to 49 used commercially available sapphire, silicon, and quartz blocks, respectively, instead of glass blocks.

Hereinafter, for convenience, blocks in Examples 47 to 49 are also referred to as “glass blocks”.

### <Content of Each Element>

In the glass block in each of Examples, a content of each element (expressed in terms of mol percentage based on oxides) was obtained by the method described above. Results are shown in the following Tables 1 to 6.

Impurity elements were Cu, Fe, Ni, Cr, Sn, Co, V, Bi, Se, Ce, Er, and Nd.

In Example 48 (silicon), for convenience, a content of the impurity element (expressed in terms of an oxide) is expressed as 100 mol %.

### <Expansion Coefficient>

An expansion coefficient of the glass block in each of Examples was obtained by the method described above. Results are shown in the following Tables 1 to 6.

### <Visible Light Transmittance>

Visible light transmittance of the glass block in each of Examples was obtained by the method described above. Results are shown in the following Tables 1 to 6.

### <Porosity>

A porosity of the glass block in each of Examples was obtained by the method described above. As a result, at least the glass blocks in Examples 1 to 33 all have porosity of 0.5 vol % or less.

### <Manufacturing Characteristics>

In each of Examples, when a temperature (melting temperature) at which the glass raw material was melted was 1,600° C. or lower, “A” was marked, when the temperature was higher than 1,600° C. and 1,650° C. or lower, “B” was marked, and when the temperature was higher than 1,650° C., “C” was marked.

If “A” or “B” was marked, manufacturing characteristics were evaluated to be excellent.

### <Etching Amount>

An etching amount was determined for the glass block in each of Examples, and plasma resistance was evaluated.

Specifically, a test piece having a size of 10 mm×5 mm×4 mm was cut out from the glass block, and a surface of 10 mm×5 mm was mirror-finished. A Kapton tape was applied as a mask to a part of the mirror-finished surface, and etching was performed with plasma gas. Thereafter, the etching amount was obtained by measuring a difference in level between an etched portion and a non-etched portion by using a stylus surface profiler (Dectak 150, manufactured by ULVAC, Inc.).

As a plasma etching apparatus, EXAM (model: POEM, manufactured by SHINKO SEIKI CO., LTD.) was used. Etching was performed with CF₄ gas for 195 minutes under a pressure of 10 Pa and an output of 350 W in a RIE mode (reactive ion etching mode).

It can be evaluated that the smaller the etching amount (unit: nm), the better the plasma resistance.

Specifically, when the etching amount was 1,600 nm or less, the plasma resistance was evaluated to be excellent. For the reason that the plasma resistance is more excellent, the etching amount is preferably 1,000 nm or less.

### <Presence or Absence of Heterogeneous Phase>

The glass block in each of Examples was visually observed, and presence or absence of a heterogeneous phase (crystalline phase, colloidal metal, ceramic particles, or the like) was observed.

When there was no heterogeneous phase, “A” was marked in the following Tables 1 to 6, when the heterogeneous phase was 10% or less of the area of the main surface of the glass block, “B” was marked, and when the heterogeneous phase was more than 10% of the area of the main surface of the glass block, “C” was marked.

If “A” or “B” was marked, transparency was evaluated to be excellent. “A” is preferable for the reason that the transparency is more excellent.

TABLE 1

| | | Example 1 | Example 2 | Example 3 | Example 4 | Example 5 |
|---|---|---|---|---|---|---|
| SiO₂ | mol % | 44.7 | 42.5 | 43.6 | 57.3 | 54.4 |
| B₂O₃ | mol % | 0.0 | 0.0 | 0.0 | 0.0 | 0.0 |
| P₂O₅ | mol % | 0.0 | 0.0 | 0.0 | 0.0 | 0.0 |
| GeO₂ | mol % | 0.0 | 0.0 | 0.0 | 0.0 | 0.0 |
| N₂ | mass % | 0.0 | 0.0 | 0.0 | 0.0 | 0.0 |
| Al₂O₃ | mol % | 0.0 | 0.0 | 0.0 | 0.0 | 5.0 |
| Ga₂O₃ | mol % | 0.0 | 0.0 | 0.0 | 0.0 | 0.0 |
| In₂O₃ | mol % | 0.0 | 0.0 | 0.0 | 0.0 | 0.0 |
| a (SiO₂ + B₂O₃ + P₂O₅ + GeO₂) | mol % | 44.7 | 42.5 | 43.6 | 57.3 | 54.4 |
| b (Al₂O₃ + Ga₂O₃ + In₂O₃) | mol % | 0.0 | 0.0 | 0.0 | 0.0 | 5.0 |
| b/a | — | 0.00 | 0.00 | 0.00 | 0.00 | 0.09 |
| a + Al₂O₃ | mol % | 44.7 | 42.5 | 43.6 | 57.3 | 59.4 |
| MgO | mol % | 26.6 | 7.0 | 17.1 | 12.6 | 12.0 |
| CaO | mol % | 28.7 | 50.5 | 39.3 | 30.1 | 28.6 |
| SrO | mol % | 0.0 | 0.0 | 0.0 | 0.0 | 0.0 |
| BaO | mol % | 0.0 | 0.0 | 0.0 | 0.0 | 0.0 |
| MgO + CaO | mol % | 55.3 | 57.5 | 56.4 | 42.7 | 40.6 |
| R²O (MgO + CaO + SrO + BaO) | mol % | 55.3 | 57.5 | 56.4 | 42.7 | 40.6 |
| Y₂O₃ | mol % | 0.0 | 0.0 | 0.0 | 0.0 | 0.0 |
| Li₂O | mol % | 0.0 | 0.0 | 0.0 | 0.0 | 0.0 |
| Na₂O | mol % | 0.0 | 0.0 | 0.0 | 0.0 | 0.0 |
| K₂O | mol % | 0.0 | 0.0 | 0.0 | 0.0 | 0.0 |
| R¹₂O (Li₂O + Na₂O + K₂O) | mol % | 0.0 | 0.0 | 0.0 | 0.0 | 0.0 |
| TiO₂ | mol % | 0.0 | 0.0 | 0.0 | 0.0 | 0.0 |
| ZrO₂ | mol % | 0.0 | 0.0 | 0.0 | 0.0 | 0.0 |
| MnO₂ | mol % | 0.0 | 0.0 | 0.0 | 0.0 | 0.0 |
| ZnO | mol % | 0.0 | 0.0 | 0.0 | 0.0 | 0.0 |
| Ta₂O₅ | mol % | 0.0 | 0.0 | 0.0 | 0.0 | 0.0 |
| Ta₂O₅/SiO₂ | — | 0.000 | 0.000 | 0.000 | 0.000 | 0.000 |
| Impurity element | mol % | 0.0 | 0.0 | 0.0 | 0.0 | 0.0 |
| (in terms of oxide) | | | | | | |
| F/O | — | 0 | 0 | 0 | 0 | 0 |
| Expansion coefficient | ppm/° C. | 8.9 | 9.1 | 9.0 | 7.2 | 6.9 |
| Visible light transmittance | % | 90% or less | 90% or less | 90% or more | 90% or more | 90% or more |
| Manufacturing characteristics | — | B | B | A | A | A |
| Etching amount | nm | 161 | 703.5 | 181.5 | 210.5 | 206 |
| Presence or absence of | — | B | B | A | A | A |
| heterogeneous phase | | | | | | |

| | | Example 6 | Example 7 | Example 8 | Example 9 |
|---|---|---|---|---|---|
| SiO₂ | mol % | 54.4 | 50.0 | 57.3 | 43.6 |
| B₂O₃ | mol % | 0.0 | 0.0 | 0.0 | 0.0 |
| P₂O₅ | mol % | 0.0 | 0.0 | 0.0 | 0.0 |
| GeO₂ | mol % | 0.0 | 0.0 | 0.0 | 0.0 |
| N₂ | mass % | 0.0 | 0.0 | 0.0 | 0.0 |
| Al₂O₃ | mol % | 0.0 | 0.0 | 0.0 | 0.0 |
| Ga₂O₃ | mol % | 0.0 | 0.0 | 0.0 | 0.0 |
| In₂O₃ | mol % | 0.0 | 0.0 | 0.0 | 0.0 |
| a (SiO₂ + B₂O₃ + P₂O₅ + GeO₂) | mol % | 54.4 | 50.0 | 57.3 | 43.6 |
| b (Al₂O₃ + Ga₂O₃ + In₂O₃) | mol % | 0.0 | 0.0 | 0.0 | 0.0 |
| b/a | — | 0.00 | 0.00 | 0.00 | 0.00 |
| a + Al₂O₃ | mol % | 54.4 | 50.0 | 57.3 | 43.6 |
| MgO | mol % | 12.0 | 25.0 | 11.1 | 39.3 |
| CaO | mol % | 28.6 | 25.0 | 26.6 | 17.1 |
| SrO | mol % | 5.0 | 0.0 | 5.0 | 0.0 |
| BaO | mol % | 0.0 | 0.0 | 0.0 | 0.0 |
| MgO + CaO | mol % | 40.6 | 50.0 | 37.7 | 56.4 |
| R²O (MgO + CaO + SrO + BaO) | mol % | 45.6 | 50.0 | 42.7 | 56.4 |
| Y₂O₃ | mol % | 0.0 | 0.0 | 0.0 | 0.0 |
| Li₂O | mol % | 0.0 | 0.0 | 0.0 | 0.0 |
| Na₂O | mol % | 0.0 | 0.0 | 0.0 | 0.0 |
| K₂O | mol % | 0.0 | 0.0 | 0.0 | 0.0 |
| R¹₂O (Li₂O + Na₂O + K₂O) | mol % | 0.0 | 0.0 | 0.0 | 0.0 |
| TiO₂ | mol % | 0.0 | 0.0 | 0.0 | 0.0 |
| ZrO₂ | mol % | 0.0 | 0.0 | 0.0 | 0.0 |
| MnO₂ | mol % | 0.0 | 0.0 | 0.0 | 0.0 |
| ZnO | mol % | 0.0 | 0.0 | 0.0 | 0.0 |
| Ta₂O₅ | mol % | 0.0 | 0.0 | 0.0 | 0.0 |
| Ta₂O₅/SiO₂ | — | 0.000 | 0.000 | 0.000 | 0.000 |
| Impurity element | mol % | 0.0 | 0.0 | 0.0 | 0.0 |
| (in terms of oxide) | | | | | |
| F/O | — | 0 | 0 | 0 | 0 |
| Expansion coefficient | ppm/° C. | 7.9 | 8.1 | 7.5 | 9.1 |
| Visible light transmittance | % | 90% or more | 90% or less | 90% or more | 90% or less |
| Manufacturing characteristics | — | A | B | A | B |
| Etching amount | nm | 262 | 197 | 262 | 222 |
| Presence or absence of | — | A | B | A | B |
| heterogeneous phase | | | | | |

TABLE 2

| | | Example 10 | Example 11 | Example 12 | Example 13 | Example 14 |
|---|---|---|---|---|---|---|
| SiO₂ | mol % | 43.6 | 39.6 | 50.0 | 50.0 | 36.1 |
| B₂O₃ | mol % | 0.0 | 0.0 | 0.0 | 0.0 | 0.0 |
| P₂O₅ | mol % | 0.0 | 0.0 | 0.0 | 0.0 | 0.0 |
| GeO₂ | mol % | 0.0 | 0.0 | 0.0 | 0.0 | 0.0 |
| N₂ | mass % | 0.0 | 0.0 | 0.0 | 0.0 | 0.0 |
| Al₂O₃ | mol % | 0.0 | 15.8 | 0.0 | 0.0 | 0.0 |
| Ga₂O₃ | mol % | 0.0 | 0.0 | 0.0 | 0.0 | 0.0 |
| In₂O₃ | mol % | 0.0 | 0.0 | 0.0 | 0.0 | 0.0 |
| a (SiO₂ + B₂O₃ + P₂O₅ + GeO₂) | mol % | 43.6 | 39.6 | 50.0 | 50.0 | 36.1 |
| b (Al₂O₃ + Ga₂O₃ + In₂O₃) | mol % | 0.0 | 15.8 | 0.0 | 0.0 | 0.0 |
| b/a | — | 0.00 | 0.40 | 0.00 | 0.00 | 0.00 |
| a + Al₂O₃ | mol % | 43.6 | 55.4 | 50.0 | 50.0 | 36.1 |
| MgO | mol % | 28.2 | 44.6 | 25.0 | 30.3 | 43.0 |
| CaO | mol % | 28.2 | 0.0 | 25.0 | 19.7 | 0.0 |
| SrO | mol % | 0.0 | 0.0 | 0.0 | 0.0 | 20.9 |
| BaO | mol % | 0.0 | 0.0 | 0.0 | 0.0 | 0.0 |
| MgO + CaO | mol % | 56.4 | 44.6 | 50.0 | 50.0 | 43.0 |
| R²O (MgO + CaO + SrO + BaO) | mol % | 56.4 | 44.6 | 50.0 | 50.0 | 63.9 |
| Y₂O₃ | mol % | 0.0 | 0.0 | 0.0 | 0.0 | 0.0 |
| Li₂O | mol % | 0.0 | 0.0 | 0.0 | 0.0 | 0.0 |
| Na₂O | mol % | 0.0 | 0.0 | 0.0 | 0.0 | 0.0 |
| K₂O | mol % | 0.0 | 0.0 | 0.0 | 0.0 | 0.0 |
| R¹₂O (Li₂O + Na₂O + K₂O) | mol % | 0.0 | 0.0 | 0.0 | 0.0 | 0.0 |
| TiO₂ | mol % | 0.0 | 0.0 | 0.0 | 0.0 | 0.0 |
| ZrO₂ | mol % | 0.0 | 0.0 | 0.0 | 0.0 | 0.0 |
| MnO₂ | mol % | 0.0 | 0.0 | 0.0 | 0.0 | 0.0 |
| ZnO | mol % | 0.0 | 0.0 | 0.0 | 0.0 | 0.0 |
| Ta₂O₅ | mol % | 0.0 | 0.0 | 0.0 | 0.0 | 0.0 |
| Ta₂O₅/SiO₂ | — | 0.000 | 0.000 | 0.000 | 0.000 | 0.000 |
| Impurity element | mol % | 0.0 | 0.0 | 0.0 | 0.0 | 0.0 |
| (in terms of oxide) | | | | | | |
| F/O | — | 0 | 0 | 0 | 0 | 0 |
| Expansion coefficient | ppm/° C. | 9.0 | 7.1 | 6.8 | 6.8 | 11.8 |
| Visible light transmittance | % | 90% or less | 90% or more | 90% or more | 90% or more | 90% or more |
| Manufacturing characteristics | — | B | B | A | A | A |
| Etching amount | nm | 212 | 411 | 313 | 576 | 1039 |
| Presence or absence of | — | B | B | A | A | A |
| heterogeneous phase | | | | | | |

| | | Example 15 | Example 16 | Example 17 | Example 18 |
|---|---|---|---|---|---|
| SiO₂ | mol % | 51.0 | 52.0 | 52.0 | 45.7 |
| B₂O₃ | mol % | 3.5 | 0.0 | 0.0 | 0.0 |
| P₂O₅ | mol % | 0.0 | 0.0 | 5.0 | 11.2 |
| GeO₂ | mol % | 4.0 | 0.0 | 0.0 | 0.0 |
| N₂ | mass % | 0.0 | 0.0 | 0.0 | 0.0 |
| Al₂O₃ | mol % | 0.0 | 0.0 | 0.0 | 0.0 |
| Ga₂O₃ | mol % | 1.0 | 0.0 | 0.0 | 0.0 |
| In₂O₃ | mol % | 0.0 | 0.0 | 0.0 | 0.0 |
| a (SiO₂ + B₂O₃ + P₂O₅ + GeO₂) | mol % | 58.5 | 52.0 | 57.0 | 56.9 |
| b (Al₂O₃ + Ga₂O₃ + In₂O₃) | mol % | 1.0 | 0.0 | 0.0 | 0.0 |
| b/a | — | 0.02 | 0.00 | 0.00 | 0.00 |
| a + Al₂O₃ | mol % | 58.5 | 52.0 | 57.0 | 56.9 |
| MgO | mol % | 15.0 | 12.0 | 22.0 | 22.1 |
| CaO | mol % | 25.0 | 27.0 | 19.0 | 19.2 |
| SrO | mol % | 0.0 | 0.0 | 2.0 | 1.8 |
| BaO | mol % | 0.0 | 0.0 | 0.0 | 0.0 |
| MgO + CaO | mol % | 40.0 | 39.0 | 41.0 | 41.3 |
| R²O (MgO + CaO + SrO + BaO) | mol % | 40.0 | 39.0 | 43.0 | 43.1 |
| Y₂O₃ | mol % | 0.0 | 0.0 | 0.0 | 0.0 |
| Li₂O | mol % | 0.0 | 0.0 | 0.0 | 0.0 |
| Na₂O | mol % | 0.5 | 0.0 | 0.0 | 0.0 |
| K₂O | mol % | 0.0 | 0.0 | 0.0 | 0.0 |
| R¹₂O (Li₂O + Na₂O + K₂O) | mol % | 0.5 | 0.0 | 0.0 | 0.0 |
| TiO₂ | mol % | 0.0 | 0.0 | 0.0 | 0.0 |
| ZrO₂ | mol % | 0.0 | 3.0 | 0.0 | 0.0 |
| MnO₂ | mol % | 0.0 | 3.0 | 0.0 | 0.0 |
| ZnO | mol % | 0.0 | 2.0 | 0.0 | 0.0 |
| Ta₂O₅ | mol % | 0.0 | 1.0 | 0.0 | 0.0 |
| Ta₂O₅/SiO₂ | — | 0.000 | 0.019 | 0.000 | 0.000 |
| Impurity element | mol % | 0.0 | 0.0 | 0.0 | 0.0 |
| (in terms of oxide) | | | | | |
| F/O | — | 0 | 0 | 0 | 0 |
| Expansion coefficient | ppm/° C. | 7.5 | 7.7 | 7.8 | 8.2 |
| Visible light transmittance | % | 90% or more | 90% or more | 90% or more | 90% or more |
| Manufacturing characteristics | — | A | A | A | A |
| Etching amount | nm | 890 | 1082 | 920 | 1342 |
| Presence or absence of | — | A | B | A | A |
| heterogeneous phase | | | | | |

TABLE 3

| | | Example | Example | Example | Example | Example |
|---|---|---|---|---|---|---|
| | | 19 | 20 | 21 | 22 | 23 |
| SiO₂ | mol % | 49.0 | 24.9 | 45.8 | 50.0 | 52.2 |
| B₂O₃ | mol % | 0.0 | 25.1 | 0.0 | 0.0 | 4.4 |
| P₂O₅ | mol % | 0.0 | 0.0 | 11.2 | 0.0 | 0.0 |
| GeO₂ | mol % | 0.0 | 0.0 | 0.0 | 0.0 | 0.0 |
| N₂ | mass % | 0.0 | 0.0 | 0.0 | 0.0 | 0.0 |
| Al₂O₃ | mol % | 0.0 | 0.0 | 0.0 | 0.0 | 0.0 |
| Ga₂O₃ | mol % | 0.0 | 0.0 | 0.0 | 5.0 | 0.0 |
| In₂O₃ | mol % | 0.0 | 0.0 | 0.0 | 0.0 | 0.0 |
| a (SiO₂ + B₂O₃ + P₂O₅ + GeO₂) | mol % | 49.0 | 50.0 | 57.0 | 50.0 | 56.6 |
| b (Al₂O₃ + Ga₂O₃ + In₂O₃) | mol % | 0.0 | 0.0 | 0.0 | 5.0 | 0.0 |
| b/a | — | 0.00 | 0.00 | 0.00 | 0.10 | 0.00 |
| a + Al₂O₃ | mol % | 49.0 | 50.0 | 57.0 | 50.0 | 56.6 |
| MgO | mol % | 16.5 | 18.5 | 22.1 | 15.8 | 12.1 |
| CaO | mol % | 28.0 | 24.5 | 19.2 | 25.2 | 26.7 |
| SrO | mol % | 4.0 | 7.0 | 1.7 | 4.0 | 0.0 |
| BaO | mol % | 0.0 | 0.0 | 0.0 | 0.0 | 0.0 |
| MgO + CaO | mol % | 44.5 | 43.0 | 41.3 | 41.0 | 38.8 |
| R²O (MgO + CaO + SrO + BaO) | mol % | 48.5 | 50.0 | 43.0 | 45.0 | 38.8 |
| Y₂O₃ | mol % | 0.0 | 0.0 | 0.0 | 0.0 | 0.0 |
| Li₂O | mol % | 0.0 | 0.0 | 0.0 | 0.0 | 0.0 |
| Na₂O | mol % | 0.0 | 0.0 | 0.0 | 0.0 | 0.0 |
| K₂O | mol % | 0.0 | 0.0 | 0.0 | 0.0 | 0.0 |
| R¹₂O (Li₂O + Na₂O + K₂O) | mol % | 0.0 | 0.0 | 0.0 | 0.0 | 0.0 |
| TiO₂ | mol % | 2.5 | 0.0 | 0.0 | 0.0 | 1.1 |
| ZrO₂ | mol % | 0.0 | 0.0 | 0.0 | 0.0 | 3.5 |
| MnO₂ | mol % | 0.0 | 0.0 | 0.0 | 0.0 | 0.0 |
| ZnO | mol % | 0.0 | 0.0 | 0.0 | 0.0 | 0.0 |
| Ta₂O₅ | mol % | 0.0 | 0.0 | 0.0 | 0.0 | 0.0 |
| Ta₂O₅/SiO₂ | — | 0.000 | 0.000 | 0.000 | 0.000 | 0.000 |
| Impurity element | mol % | 0.0 | 0.0 | 0.0 | 0.0 | 0.0 |
| (in terms of oxide) | | | | | | |
| F/O | — | 0 | 0 | 0 | 0 | 0 |
| Expansion coefficient | ppm/° C. | 8.3 | 8.7 | 8.4 | 7.6 | 7.0 |
| Visible light transmittance | % | 90% or more | 90% or more | 90% or more | 90% or more | 90% or more |
| Manufacturing characteristics | — | A | A | A | A | A |
| Etching amount | nm | 975 | 1558 | 1493 | 1258 | 1298 |
| Presence or absence of | — | A | A | A | B | A |
| heterogeneous phase | | | | | | |

| | | Example 24 | Example 25 | Example 26 | Example 27 |
|---|---|---|---|---|---|
| SiO₂ | mol % | 40.2 | 45.0 | 53.5 | 53.0 |
| B₂O₃ | mol % | 10.0 | 2.0 | 0.0 | 4.0 |
| P₂O₅ | mol % | 0.0 | 1.5 | 0.0 | 0.0 |
| GeO₂ | mol % | 0.0 | 0.0 | 0.0 | 0.0 |
| N₂ | mass % | 0.0 | 0.0 | 0.0 | 0.0 |
| Al₂O₃ | mol % | 0.0 | 0.0 | 0.0 | 0.0 |
| Ga₂O₃ | mol % | 0.0 | 0.0 | 0.0 | 0.0 |
| In₂O₃ | mol % | 0.0 | 0.0 | 0.0 | 0.0 |
| a (SiO₂ + B₂O₃ + P₂O₅ + GeO₂) | mol % | 50.2 | 48.5 | 53.5 | 57.0 |
| b (Al₂O₃ + Ga₂O₃ + In₂O₃) | mol % | 0.0 | 0.0 | 0.0 | 0.0 |
| b/a | — | 0.00 | 0.00 | 0.00 | 0.00 |
| a + Al₂O₃ | mol % | 50.2 | 48.5 | 53.5 | 57.0 |
| MgO | mol % | 17.0 | 15.0 | 12.0 | 14.0 |
| CaO | mol % | 24.0 | 23.0 | 24.5 | 24.2 |
| SrO | mol % | 0.0 | 2.0 | 5.0 | 0.0 |
| BaO | mol % | 0.0 | 0.0 | 2.0 | 0.0 |
| MgO + CaO | mol % | 41.0 | 38.0 | 36.5 | 38.2 |
| R²O (MgO + CaO + SrO + BaO) | mol % | 41.0 | 40.0 | 43.5 | 38.2 |
| Y₂O₃ | mol % | 0.0 | 0.0 | 0.0 | 4.8 |
| Li₂O | mol % | 0.0 | 0.0 | 0.0 | 0.0 |
| Na₂O | mol % | 0.0 | 0.0 | 0.0 | 0.0 |
| K₂O | mol % | 0.0 | 0.0 | 0.0 | 0.0 |
| R¹₂O (Li₂O + Na₂O + K₂O) | mol % | 0.0 | 0.0 | 0.0 | 0.0 |
| TiO₂ | mol % | 0.0 | 0.0 | 0.0 | 0.0 |
| ZrO₂ | mol % | 0.0 | 0.0 | 0.0 | 0.0 |
| MnO₂ | mol % | 8.8 | 0.0 | 0.0 | 0.0 |
| ZnO | mol % | 0.0 | 11.5 | 0.0 | 0.0 |
| Ta₂O₅ | mol % | 0.0 | 0.0 | 3.0 | 0.0 |
| Ta₂O₅/SiO₂ | — | 0.000 | 0.000 | 0.056 | 0.000 |
| Impurity element | mol % | 0.0 | 0.0 | 0.0 | 0.0 |
| (in terms of oxide) | | | | | |
| F/O | — | 0 | 0 | 0 | 0 |
| Expansion coefficient | ppm/° C. | 8.0 | 8.3 | 7.7 | 6.8 |
| Visible light transmittance | % | 90% or more | 90% or more | 90% or more | 90% or more |
| Manufacturing characteristics | — | A | A | A | A |
| Etching amount | nm | 1439 | 1584 | 1191 | 702 |
| Presence or absence of | — | A | A | B | A |
| heterogeneous phase | | | | | |

TABLE 4

| | | Example | Example | Example | Example | Example |
|---|---|---|---|---|---|---|
| | | 28 | 29 | 30 | 31 | 32 |
| SiO₂ | mol % | 53.0 | 53.0 | 53.0 | 50.0 | 53.0 |
| B₂O₃ | mol % | 4.0 | 4.0 | 4.0 | 0.0 | 0.0 |
| P₂O₅ | mol % | 0.0 | 0.0 | 0.0 | 0.0 | 0.0 |
| GeO₂ | mol % | 0.0 | 0.0 | 0.0 | 0.0 | 0.0 |
| N₂ | mass % | 0.2 | 3.5 | 7.1 | 0.0 | 0.0 |
| Al₂O₃ | mol % | 0.0 | 0.0 | 0.0 | 0.0 | 2.0 |
| Ga₂O₃ | mol % | 0.0 | 0.0 | 0.0 | 0.0 | 0.0 |
| In₂O₃ | mol % | 0.0 | 0.0 | 0.0 | 0.0 | 0.0 |
| a (SiO₂ + B₂O₃ + P₂O₅ + GeO₂) | mol % | 57.0 | 57.0 | 57.0 | 50.0 | 53.0 |
| b (Al₂O₃ + Ga₂O₃ + In₂O₃) | mol % | 0.0 | 0.0 | 0.0 | 0.0 | 2.0 |
| b/a | — | 0.00 | 0.00 | 0.00 | 0.00 | 0.04 |
| a + Al₂O₃ | mol % | 57.0 | 57.0 | 57.0 | 50.0 | 55.0 |
| MgO | mol % | 14.0 | 14.0 | 14.0 | 18.0 | 30.0 |
| CaO | mol % | 23.0 | 23.0 | 23.0 | 29.0 | 10.0 |
| SrO | mol % | 5.0 | 5.0 | 5.0 | 0.0 | 5.0 |
| BaO | mol % | 1.0 | 1.0 | 1.0 | 0.0 | 0.0 |
| MgO + CaO | mol % | 37.0 | 37.0 | 37.0 | 47.0 | 40.0 |
| R²O (MgO + CaO + SrO + BaO) | mol % | 43.0 | 43.0 | 43.0 | 47.0 | 45.0 |
| Y₂O₃ | mol % | 0.0 | 0.0 | 0.0 | 0.0 | 0.0 |
| Li₂O | mol % | 0.0 | 0.0 | 0.0 | 0.0 | 0.0 |
| Na₂O | mol % | 0.0 | 0.0 | 0.0 | 0.0 | 0.0 |
| K₂O | mol % | 0.0 | 0.0 | 0.0 | 0.0 | 0.0 |
| R¹₂O (Li₂O + Na₂O + K₂O) | mol % | 0.0 | 0.0 | 0.0 | 0.0 | 0.0 |
| TiO₂ | mol % | 0.0 | 0.0 | 0.0 | 0.0 | 0.0 |
| ZrO₂ | mol % | 0.0 | 0.0 | 0.0 | 0.0 | 0.0 |
| MnO₂ | mol % | 0.0 | 0.0 | 0.0 | 0.0 | 0.0 |
| ZnO | mol % | 0.0 | 0.0 | 0.0 | 0.0 | 0.0 |
| Ta₂O₅ | mol % | 0.0 | 0.0 | 0.0 | 0.0 | 0.0 |
| Ta₂O₅/SiO₂ | — | 0.000 | 0.000 | 0.000 | 0.000 | 0.000 |
| Impurity element | mol % | 0.0 | 0.0 | 0.0 | 3.0 | 0.0 |
| (in terms of oxide) | | | | | | |
| F/O | — | 0 | 0 | 0 | 0 | 0.10 |
| Expansion coefficient | ppm/° C. | 7.5 | 7.5 | 7.5 | 8.0 | 7.6 |
| Visible light transmittance | % | 90% or | 90% or less | 90% or less | 90% or more | 90% or more |
| | | more | | | | |
| Manufacturing characteristics | — | B | B | B | B | A |
| Etching amount | nm | 604 | 594 | 579 | 982 | 1102 |
| Presence or absence of | — | A | A | A | A | A |
| heterogeneous phase | | | | | | |

| | | Example 33 | Example 34 | Example 35 | Example 36 |
|---|---|---|---|---|---|
| SiO₂ | mol % | 42.2 | 70.0 | 40.0 | 50.0 |
| B₂O₃ | mol % | 0.0 | 0.0 | 0.0 | 0.0 |
| P₂O₅ | mol % | 0.0 | 0.0 | 0.0 | 0.0 |
| GeO₂ | mol % | 0.0 | 0.0 | 0.0 | 0.0 |
| N₂ | mass % | 0.0 | 0.0 | 0.0 | 0.0 |
| Al₂O₃ | mol % | 0.0 | 0.0 | 0.0 | 0.0 |
| Ga₂O₃ | mol % | 0.0 | 0.0 | 0.0 | 5.5 |
| In₂O₃ | mol % | 0.0 | 0.0 | 0.0 | 0.0 |
| a (SiO₂ + B₂O₃ + P₂O₅ + GeO₂) | mol % | 42.2 | 70.0 | 40.0 | 50.0 |
| b (Al₂O₃ + Ga₂O₃ + In₂O₃) | mol % | 0.0 | 0.0 | 0.0 | 5.5 |
| b/a | — | 0.00 | 0.00 | 0.00 | 0.11 |
| a + Al₂O₃ | mol % | 42.2 | 70.0 | 40.0 | 50.0 |
| MgO | mol % | 7.0 | 10.0 | 60.0 | 20.0 |
| CaO | mol % | 50.1 | 10.0 | 0.0 | 0.0 |
| SrO | mol % | 0.0 | 0.0 | 0.0 | 24.5 |
| BaO | mol % | 0.0 | 0.0 | 0.0 | 0.0 |
| MgO + CaO | mol % | 57.1 | 20.0 | 60.0 | 20.0 |
| R²O (MgO + CaO + SrO + BaO) | mol % | 57.1 | 20.0 | 60.0 | 44.5 |
| Y₂O₃ | mol % | 0.0 | 0.0 | 0.0 | 0.0 |
| Li₂O | mol % | 0.0 | 0.0 | 0.0 | 0.0 |
| Na₂O | mol % | 0.0 | 10.0 | 0.0 | 0.0 |
| K₂O | mol % | 0.0 | 0.0 | 0.0 | 0.0 |
| R¹₂O (Li₂O + Na₂O + K₂O) | mol % | 0.0 | 10.0 | 0.0 | 0.0 |
| TiO₂ | mol % | 0.0 | 0.0 | 0.0 | 0.0 |
| ZrO₂ | mol % | 0.0 | 0.0 | 0.0 | 0.0 |
| MnO₂ | mol % | 0.0 | 0.0 | 0.0 | 0.0 |
| ZnO | mol % | 0.0 | 0.0 | 0.0 | 0.0 |
| Ta₂O₅ | mol % | 0.0 | 0.0 | 0.0 | 0.0 |
| Ta₂O₅/SiO₂ | — | 0.000 | 0.000 | 0.000 | 0.000 |
| Impurity element | mol % | 0.7 | 0.0 | 0.0 | 0.0 |
| (in terms of oxide) | | | | | |
| F/O | — | 0 | 0 | 0 | 0 |
| Expansion coefficient | ppm/° C. | 9.1 | 7.9 | — | 10.4 |
| Visible light transmittance | % | 90% or less | 90% or more | 90% or less | 90% or more |
| Manufacturing characteristics | — | B | A | C | A |
| Etching amount | nm | 788 | 4741 | — | 3023 |
| Presence or absence of | — | B | A | C | A |
| heterogeneous phase | | | | | |

TABLE 5

| | | Example | Example | Example | Example | Example |
|---|---|---|---|---|---|---|
| | | 37 | 38 | 39 | 40 | 41 |
| SiO₂ | mol % | 30.0 | 20.0 | 0.0 | 50.0 | 60.0 |
| B₂O₃ | mol % | 20.0 | 20.0 | 50.0 | 0.0 | 0.0 |
| P₂O₅ | mol % | 20.0 | 0.0 | 15.0 | 0.0 | 0.0 |
| GeO₂ | mol % | 0.0 | 0.0 | 0.0 | 0.0 | 0.0 |
| N₂ | mass % | 0.0 | 0.0 | 0.0 | 0.0 | 0.0 |
| Al₂O₃ | mol % | 0.0 | 22.0 | 0.0 | 0.0 | 0.0 |
| Ga₂O₃ | mol % | 0.0 | 8.0 | 0.0 | 20.0 | 0.0 |
| In₂O₃ | mol % | 0.0 | 0.0 | 0.0 | 0.0 | 0.0 |
| a (SiO₂ + B₂O₃ + P₂O₅ + GeO₂) | mol % | 70.0 | 40.0 | 65.0 | 50.0 | 60.0 |
| b (Al₂O₃ + Ga₂O₃ + In₂O₃) | mol % | 0.0 | 30.0 | 0.0 | 20.0 | 0.0 |
| b/a | — | 0.00 | 0.75 | 0.00 | 0.40 | 0.00 |
| a + Al₂O₃ | mol % | 70.0 | 62.0 | 65.0 | 50.0 | 60.0 |
| MgO | mol % | 20.0 | 20.0 | 25.0 | 20.0 | 10.0 |
| CaO | mol % | 10.0 | 10.0 | 10.0 | 10.0 | 10.0 |
| SrO | mol % | 0.0 | 0.0 | 0.0 | 0.0 | 0.0 |
| BaO | mol % | 0.0 | 0.0 | 0.0 | 0.0 | 0.0 |
| MgO + CaO | mol % | 30.0 | 30.0 | 35.0 | 30.0 | 20.0 |
| R²O (MgO + CaO + SrO + BaO) | mol % | 30.0 | 30.0 | 35.0 | 30.0 | 20.0 |
| Y₂O₃ | mol % | 0.0 | 0.0 | 0.0 | 0.0 | 0.0 |
| Li₂O | mol % | 0.0 | 0.0 | 0.0 | 0.0 | 0.0 |
| Na₂O | mol % | 0.0 | 0.0 | 0.0 | 0.0 | 0.0 |
| K₂O | mol % | 0.0 | 0.0 | 0.0 | 0.0 | 0.0 |
| R¹₂O (Li₂O + Na₂O + K₂O) | mol % | 0.0 | 0.0 | 0.0 | 0.0 | 0.0 |
| TiO₂ | mol % | 0.0 | 0.0 | 0.0 | 0.0 | 20.0 |
| ZrO₂ | mol % | 0.0 | 0.0 | 0.0 | 0.0 | 0.0 |
| MnO₂ | mol % | 0.0 | 0.0 | 0.0 | 0.0 | 0.0 |
| ZnO | mol % | 0.0 | 0.0 | 0.0 | 0.0 | 0.0 |
| Ta₂O₅ | mol % | 0.0 | 0.0 | 0.0 | 0.0 | 0.0 |
| Ta₂O₅/SiO₂ | — | 0.000 | 0.000 | — | 0.000 | 0.000 |
| Impurity element | mol % | 0.0 | 0.0 | 0.0 | 0.0 | 0.0 |
| (in terms of oxide) | | | | | | |
| F/O | | 0 | 0 | 0 | 0 | 0 |
| Expansion coefficient | ppm/° C. | 5.4 | — | — | — | — |
| Visible light transmittance | % | 90% or less | 90% or less | 90% or less | 90% or less | 90% or less |
| Manufacturing characteristics | — | C | C | C | C | C |
| Etching amount | nm | 2243 | 2343 | 1796 | 2006 | 4021 |
| Presence or absence of | — | A | C | A | C | A |
| heterogeneous phase | | | | | | |

| | | Example 42 | Example 43 | Example 44 | Example 45 |
|---|---|---|---|---|---|
| SiO₂ | mol % | 70.0 | 65.0 | 50.0 | 50.0 |
| B₂O₃ | mol % | 0.0 | 0.0 | 0.0 | 0.0 |
| P₂O₅ | mol % | 0.0 | 0.0 | 0.0 | 0.0 |
| GeO₂ | mol % | 0.0 | 0.0 | 0.0 | 0.0 |
| N₂ | mass % | 0.0 | 0.0 | 0.0 | 0.0 |
| Al₂O₃ | mol % | 0.0 | 0.0 | 0.0 | 0.0 |
| Ga₂O₃ | mol % | 0.0 | 0.0 | 0.0 | 0.0 |
| In₂O₃ | mol % | 0.0 | 0.0 | 0.0 | 0.0 |
| a (SiO₂ + B₂O₃ + P₂O₅ + GeO₂) | mol % | 70.0 | 65.0 | 50.0 | 50.0 |
| b (Al₂O₃ + Ga₂O₃ + In₂O₃) | mol % | 0.0 | 0.0 | 0.0 | 0.0 |
| b/a | — | 0.00 | 0.00 | 0.00 | 0.00 |
| a + Al₂O₃ | mol % | 70.0 | 65.0 | 50.0 | 50.0 |
| MgO | mol % | 10.0 | 10.0 | 20.0 | 20.0 |
| CaO | mol % | 10.0 | 10.0 | 10.0 | 10.0 |
| SrO | mol % | 0.0 | 0.0 | 0.0 | 0.0 |
| BaO | mol % | 0.0 | 0.0 | 0.0 | 0.0 |
| MgO + CaO | mol % | 20.0 | 20.0 | 30.0 | 30.0 |
| R²O (MgO + CaO + SrO + BaO) | mol % | 20.0 | 20.0 | 30.0 | 30.0 |
| Y₂O₃ | mol % | 0.0 | 0.0 | 0.0 | 0.0 |
| Li₂O | mol % | 0.0 | 0.0 | 0.0 | 0.0 |
| Na₂O | mol % | 0.0 | 0.0 | 0.0 | 0.0 |
| K₂O | mol % | 0.0 | 0.0 | 0.0 | 0.0 |
| R¹₂O (Li₂O + Na₂O + K₂O) | mol % | 0.0 | 0.0 | 0.0 | 0.0 |
| TiO₂ | mol % | 0.0 | 0.0 | 0.0 | 0.0 |
| ZrO₂ | mol % | 10.0 | 0.0 | 0.0 | 0.0 |
| MnO₂ | mol % | 0.0 | 15.0 | 0.0 | 0.0 |
| ZnO | mol % | 0.0 | 0.0 | 0.0 | 20.0 |
| Ta₂O₅ | mol % | 0.0 | 0.0 | 20.0 | 0.0 |
| Ta₂O₅/SiO₂ | — | 0.000 | 0.000 | 0.400 | 0.000 |
| Impurity element | mol % | 0.0 | 0.0 | 0.0 | 0.0 |
| (in terms of oxide) | | | | | |
| F/O | — | 0 | 0 | 0 | 0 |
| Expansion coefficient | ppm/° C. | — | | — | 6.8 |
| Visible light transmittance | % | 90% or less | 90% or less | 90% or less | 90% or more |
| Manufacturing characteristics | — | C | C | C | A |
| Etching amount | nm | 4211 | 4739 | — | 4092 |
| Presence or absence of | — | A | A | C | A |
| heterogeneous phase | | | | | |

TABLE 6

| | | Example 46 | Example 47 | Example 48 | Example 49 |
|---|---|---|---|---|---|
| SiO₂ | mol % | 30.0 | 0.0 | 0.0 | 98.0 |
| B₂O₃ | mol % | 0.0 | 0.0 | 0.0 | 0.0 |
| P₂O₅ | mol % | 0.0 | 0.0 | 0.0 | 0.0 |
| GeO₂ | mol % | 0.0 | 0.0 | 0.0 | 0.0 |
| N₂ | mass % | 0.0 | 0.0 | 0.0 | 0.0 |
| Al₂O₃ | mol % | 0.0 | 100.0 | 0.0 | 0.0 |
| Ga₂O₃ | mol % | 0.0 | 0.0 | 0.0 | 0.0 |
| In₂O₃ | mol % | 0.0 | 0.0 | 0.0 | 0.0 |
| a (SiO₂ + B₂O₃ + P₂O₅ + GeO₂) | mol % | 30.0 | 0.0 | 0.0 | 98.0 |
| b (Al₂O₃ + Ga₂O₃ + In₂O₃) | mol % | 0.0 | 100.0 | 0.0 | 0.0 |
| b/a | — | 0.00 | — | — | 0.00 |
| a + Al₂O₃ | mol % | 30.0 | 100.0 | 0.0 | 98.0 |
| MgO | mol % | 20.0 | 0.0 | 0.0 | 0.0 |
| CaO | mol % | 10.0 | 0.0 | 0.0 | 0.0 |
| SrO | mol % | 0.0 | 0.0 | 0.0 | 0.0 |
| BaO | mol % | 0.0 | 0.0 | 0.0 | 0.0 |
| MgO + CaO | mol % | 30.0 | 0.0 | 0.0 | 0.0 |
| R²O (MgO + CaO + SrO + BaO) | mol % | 30.0 | 0.0 | 0.0 | 0.0 |
| Y₂O₃ | mol % | 0.0 | 0.0 | 0.0 | 0.0 |
| Li₂O | mol % | 0.0 | 0.0 | 0.0 | 0.0 |
| Na₂O | mol % | 0.0 | 0.0 | 0.0 | 0.0 |
| K₂O | mol % | 0.0 | 0.0 | 0.0 | 0.0 |
| R¹₂O (Li₂O + Na₂O + K₂O) | mol % | 0.0 | 0.0 | 0.0 | 0.0 |
| TiO₂ | mol % | 0.0 | 0.0 | 0.0 | 0.0 |
| ZrO₂ | mol % | 0.0 | 0.0 | 0.0 | 0.0 |
| MnO₂ | mol % | 0.0 | 0.0 | 0.0 | 0.0 |
| ZnO | mol % | 0.0 | 0.0 | 0.0 | 0.0 |
| Ta₂O₅ | mol % | 0.0 | 0.0 | 0.0 | 0.0 |
| Ta₂O₅/SiO₂ | — | 0.000 | — | — | 0.000 |
| Impurity element | mol % | 40.0 | 0.0 | 100.0 | 2.0 |
| (in terms of oxide) | | | | | |
| F/O | — | 0 | 0 | 0 | 0 |
| Expansion coefficient | ppm/° C. | — | 7.2 | — | — |
| Visible light transmittance | % | 90% or more | 90% or less | 90% or less | 90% or more |
| Manufacturing characteristics | — | A | C | A | A |
| Etching amount | nm | 3071 | 1006 | 13204 | 8927 |
| Presence or absence of | — | A | C | A | A |
| heterogeneous phase | | | | | |

| | | Example 50 | Example 51 | Example 52 | Example 53 |
|---|---|---|---|---|---|
| SiO₂ | mol % | 58.0 | 55.0 | 51.0 | 53.0 |
| B₂O₃ | mol % | 0.0 | 0.0 | 0.0 | 0.0 |
| P₂O₅ | mol % | 0.0 | 0.0 | 0.0 | 0.0 |
| GeO₂ | mol % | 0.0 | 0.0 | 0.0 | 0.0 |
| N₂ | mass % | 0.0 | 0.0 | 0.0 | 0.0 |
| Al₂O₃ | mol % | 5.0 | 5.0 | 0.0 | 2.0 |
| Ga₂O₃ | mol % | 0.0 | 0.0 | 0.0 | 0.0 |
| In₂O₃ | mol % | 0.0 | 0.0 | 0.0 | 0.0 |
| a (SiO₂ + B₂O₃ + P₂O₅ + GeO₂) | mol % | 58.0 | 55.0 | 51.0 | 53.0 |
| b (Al₂O₃ + Ga₂O₃ + In₂O₃) | mol % | 5.0 | 5.0 | 0.0 | 2.0 |
| b/a | — | 0.09 | 0.09 | 0.00 | 0.04 |
| a + Al₂O₃ | mol % | 63.0 | 60.0 | 51.0 | 55.0 |
| MgO | mol % | 15.0 | 15.0 | 10.0 | 5.0 |
| CaO | mol % | 10.0 | 10.0 | 25.0 | 5.0 |
| SrO | mol % | 12.0 | 0.0 | 7.0 | 35.0 |
| BaO | mol % | 0.0 | 15.0 | 2.0 | 0.0 |
| MgO + CaO | mol % | 25.0 | 25.0 | 35.0 | 10.0 |
| R²O (MgO + CaO + SrO + BaO) | mol % | 37.0 | 40.0 | 44.0 | 45.0 |
| Y₂O₃ | mol % | 0.0 | 0.0 | 0.0 | 0.0 |
| Li₂O | mol % | 0.0 | 0.0 | 5.0 | 0.0 |
| Na₂O | mol % | 0.0 | 0.0 | 0.0 | 0.0 |
| K₂O | mol % | 0.0 | 0.0 | 0.0 | 0.0 |
| R¹₂O (Li₂O + Na₂O + K₂O) | mol % | 0.0 | 0.0 | 5.0 | 0.0 |
| TiO₂ | mol % | 0.0 | 0.0 | 0.0 | 0.0 |
| ZrO₂ | mol % | 0.0 | 0.0 | 0.0 | 0.0 |
| MnO₂ | mol % | 0.0 | 0.0 | 0.0 | 0.0 |
| ZnO | mol % | 0.0 | 0.0 | 0.0 | 0.0 |
| Ta₂O₅ | mol % | 0.0 | 0.0 | 0.0 | 0.0 |
| Ta₂O₅/SiO₂ | — | 0.000 | 0.000 | 0.000 | 0.000 |
| Impurity element | mol % | 0.0 | 0.0 | 0.0 | 0.0 |
| (in terms of oxide) | | | | | |
| F/O | — | 0 | 0 | 0 | 0.40 |
| Expansion coefficient | ppm/° C. | 6.9 | 7.7 | 8.9 | 10.0 |
| Visible light transmittance | % | 90% or more | 90% or more | 90% or more | 90% or more |
| Manufacturing characteristics | — | A | A | A | A |
| Etching amount | nm | 3502 | 5011 | 2154 | 3012 |
| Presence or absence of | — | A | A | A | A |
| heterogeneous phase | | | | | |

### Conclusion of Evaluation Results

As shown in Tables 1 to 6 described above, the glass blocks in Examples 1 to 33 have excellent plasma resistance and excellent transparency.

On the other hand, in the glass blocks in Examples 34 to 53, at least one of the plasma resistance and the transparency is insufficient.

Although the present invention has been described in detail with reference to specific embodiments, it is apparent to those skilled in the art that various changes and modifications can be made without departing from the spirit and scope of the present invention. The present application is based on a Japanese patent application (Japanese Patent Application No. 2021-149104) filed on Sep. 14, 2021, a Japanese patent application (Japanese Patent Application No. 2021-167594) filed on Oct. 12, 2021, and a Japanese patent application (Japanese Patent Application No. 2021-192308) filed on Nov. 26, 2021, contents of which are incorporated herein by reference.

1. A glass block comprising:
silicon; and
at least one of magnesium and calcium, wherein
when an alkali metal element is expressed as R¹ and an alkaline earth metal element is expressed as R², in terms of mol percentage based on oxides,
a content of B₂O₃ is 49.0 mol % or less,
a content of P₂O₅ is 11.5 mol % or less,
a total of contents of SiO₂, B₂O₃, P₂O₅, and GeO₂ is 10.0 mol % or more and 59.5 mol % or less,
a total of contents of SiO₂, B₂O₃, P₂O₅, GeO₂, and Al₂O₃ is 66.5 mol % or less,
a content of Ga₂O₃ is 7.0 mol % or less,
a ratio b/a of a total b of contents of Al₂O₃, Ga₂O₃, and In₂O₃ to a total a of the contents of SiO₂, B₂O₃, P₂O₅, and GeO₂ is 0.44 or less,
a content of R²O is 20.0 mol % or more,
a content of MgO is 50.0 mol % or less,
the content of MgO is equal to or more than a content of BaO, a content of CaO is equal to or more than the content of BaO, and a content of SrO is equal to or more than the content of BaO,
the content of MgO is equal to or more than the content of SrO, and the content of CaO is equal to or more than the content of SrO,
a content of R¹₂O is 1.2 mol % or less,
a content of TiO₂ or ZrO₂ is 4.8 mol % or less,
a content of MnO₂ is 9.5 mol % or less,
a content of ZnO is 11.8 mol % or less,
a ratio Ta₂O₅/SiO₂ of a content of Ta₂O₅ to a content of SiO₂ is 0.067 or less,
a content of an impurity element in terms of an oxide is 15.0 mol % or less, provided that the impurity element is a metal element excluding silicon, boron, phosphorus, germanium, aluminum, gallium, indium, an alkaline earth metal element, yttrium, an alkali metal element, titanium, zirconium, manganese, zinc, and tantalum, and
a ratio F/O of a content F of fluorine to a content O of oxygen is 0.20 or less.

2. The glass block according to claim 1, wherein
the content of SiO₂ is 17.0 mol % or more.

3. The glass block according to claim 1, wherein
the content of SiO₂ is 59.5 mol % or less.

4. The glass block according to claim 1, wherein
the content of Al₂O₃ is 27.5 mol % or less.

5. The glass block according to claim 1, wherein
a total of the contents of MgO and CaO is 20.0 mol % or more.

6. The glass block according to claim 1, wherein
a total of the contents of MgO and CaO is 69.0 mol % or less.

7. The glass block according to claim 1, wherein
the content of CaO is 20.0 mol % or more and 69.0 mol % or less.

8. The glass block according to claim 1, wherein
the content of BaO is 30.0 mol % or less.

9. The glass block according to claim 1, having an average thermal expansion coefficient at 50° C. to 350° C. of 9.0 ppm/° C. or less.

10. The glass block according to claim 1, having a visible light transmittance of 75% or more.

11. The glass block according to claim 1, having a porosity of 3.0 vol % or less.

12. A method for manufacturing the glass block according to claim 1, the method comprising:
melting a glass raw material by heating; and
molding the obtained molten glass, followed by annealing.

13. The method for manufacturing the glass block according to claim 12, wherein
a temperature at which the glass raw material is heated and melted is 1,650° C. or lower.

14. A member for a semiconductor manufacturing apparatus comprising:
the glass block according to claim 1.

15. The member for a semiconductor manufacturing apparatus according to claim 14, wherein
the member is to be mounted on a plasma etching apparatus, and is a top plate, a microwave introduction tube, a lift pin, a nozzle, an edge ring, an electrostatic chuck, a shower plate, or a protective cover for a sensor inside a chamber.
